(19) United States
(12) Patent Application Publication
(10) Pub. No.: US 2024/0234079 A9
(43) Pub. Date: Jul. 11, 2024

(54) Ion source structure of ion implanter and its operation method

(71) Applicant: United Semiconductor (Xiamen) Co., Ltd., Xiamen (CN)

(72) Inventors: Wen Shuo Cui, Qiqihaer City (CN); WEN YI TAN, Xiamen (CN)

(73) Assignee: United Semiconductor (Xiamen) Co., Ltd., Xiamen (CN)

(21) Appl. No.: 17/993,886

(22) Filed: Nov. 24, 2022

(30) Foreign Application Priority Data
Oct. 25, 2022 (CN) 202211309816.3

(51) Int. Cl. H01J 37/08; H01J 37/24; H01J 37/317

(52) U.S. Cl. CPC H01J 37/08; H01J 37/242; H01J 37/3171

(57) ABSTRACT

The invention provides an ion source structure of an ion implanter, which comprises an arc chamber, a filament in the arc chamber, and a cathode in the arc chamber, wherein the cathode has an upper surface and a lower surface, and at least one of the upper surface and the lower surface is non-planar.

### BACKGROUND OF THE INVENTION

### 1. Field of the Invention

The present invention relates to an ion implanter, in particular to an ion source structure of an ion implanter with improved ion generation efficiency and its operation method.

### 2. Description of the Prior Art

In the semiconductor manufacturing process, the ion implanter is used to implant the region to be doped in the semiconductor wafer, and the ion source in the ion implanter is used to generate the ion beam for ion implantation.

Furthermore, the principle of ion beam generation by ion source of ion implanter is briefly described as follows: firstly, an arc chamber is provided, in which hot electrons are generated by heating filament, and then an accelerating electric field is generated by positive power supply and negative power supply in the arc chamber, so that the hot electrons hit the doping source gas in the arc chamber and dissociate to generate positively charged ions or negatively charged ions, and then the ions are guided and doped to the wafer.

However, the production of the current ion implanter still needs to be improved. To improve the ion production efficiency of the ion implanter, it is necessary to introduce gas with higher concentration, but this will increase the cost of the process.

### SUMMARY OF THE INVENTION

The invention provides an ion source structure of an ion implanter, which comprises an arc chamber, a filament in the arc chamber, and a cathode in the arc chamber, wherein the cathode has an upper surface and a lower surface, and at least one of the upper surface and the lower surface is non-planar.

The invention also provides an operation method of an ion source of an ion implanter, which comprises providing a wafer with a pattern and an ion implanter, wherein an ion source structure in the ion implanter comprises an arc chamber, a filament in the arc chamber and a cathode in the arc chamber, wherein the cathode has an upper surface and a lower surface, and at least one of the upper surface and the lower surface is non-planar, and the ion implanter is used to perform an ion implantation step on the wafer.

The invention is characterized in that the ion source structure in the ion implanter comprises a cathode with a non-planar surface, and hot electrons are generated after the filament in the arc chamber is heated, and the hot electrons hit the cathode and generate more hot electrons. Because the surface of the cathode is designed as a non-planar (non-flat) surface, its surface area is large, which can improve the generation efficiency of hot electrons, and then improve the generation efficiency of ion beams. The invention can achieve the advantage of improving productivity without increasing the flow rate of doping gas and being compatible with the existing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic cross-sectional structure of an ion source structure of an ion implanter provided by the present invention.

FIG. 2 shows a schematic structure of the cathode in the structure of FIG. 1.

FIG. 3 is a schematic diagram of the ion implantation step in which ions generated by an ion source structure in an ion implanter are guided into an arc chamber.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

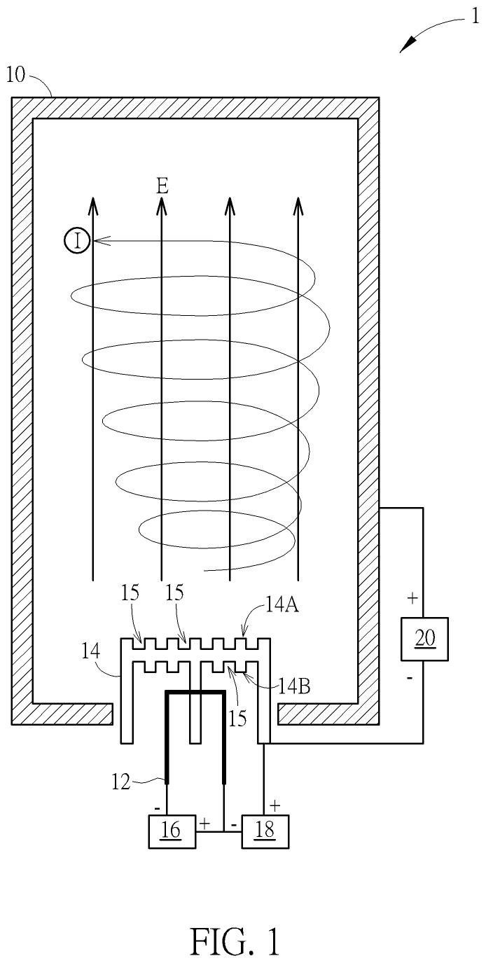

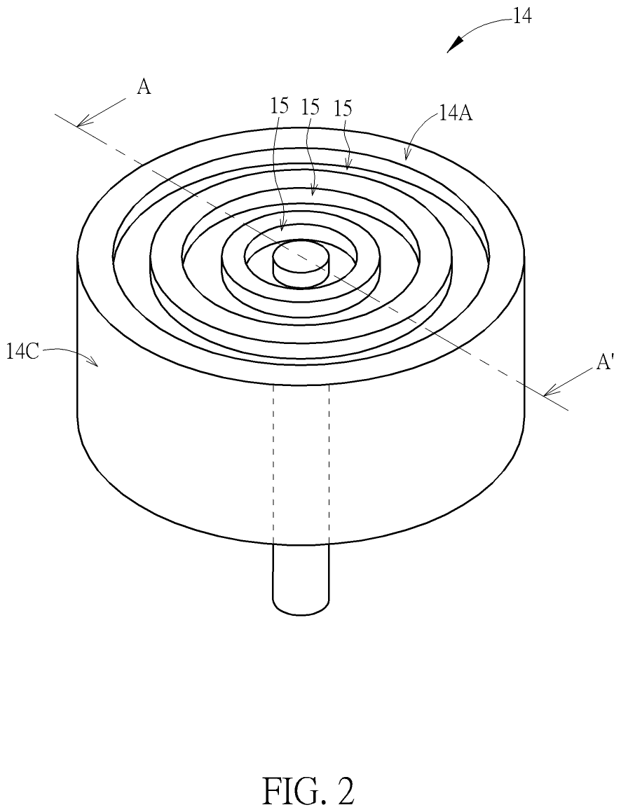

FIG. 1 shows a schematic cross-sectional structure of an ion source of an ion implanter provided by the present invention, and FIG. 2 shows a schematic structure of a cathode in the structure of FIG. 1. As shown in FIG. 1, the ion source structure 1 of the ion implanter of the present invention includes an arc chamber 10, in which a filament 12 and a cathode 14 are contained. It also includes a first power supply unit 16 and a second power supply unit 18, wherein the anode and cathode of the first power supply unit 16 are respectively connected to both ends of the filament 12, the anode of the second power supply unit 18 is connected to the cathode 14, and the cathode is connected to the filament 12. In addition, a third power supply unit 20 is included, wherein the anode of the third power supply unit 20 is connected to the arc chamber 10, and the cathode is connected to the cathode 14.

In this embodiment, the first power supply unit 16 supplies current to the filament 12, so that the temperature of the filament 12 starts to rise. When the temperature of the filament 12 rises to a certain degree (for example, higher than 1000 degrees Celsius), and hot electrons will start to be generated. The second power supply unit 18 connects the filament 12 with the cathode 14 to generate a fixed electric field E between the filament 12 and the cathode 14, so that the hot electrons generated by the filament 12 travel along the electric field toward the cathode 14 and hit the cathode 14. After the cathode 14 is hit by the hot electrons, its temperature will also rise and more hot electrons will be generated. The third power supply unit 20 connects the arc chamber 10 with the cathode 14 to generate an accelerating electric field in a fixed direction in the arc chamber 10. When the above-mentioned hot electrons generated by the cathode 14 are attracted by the accelerating electric field, they will become high-energy hot electrons and be emitted toward the arc chamber 10. After these high-energy hot electrons hit the doping source gas introduced into the arc chamber 10, the doping source gas will be dissociated, and positive ions and negative ions (denoted by ion I in FIG. 1) will be generated. These ions are used in the subsequent ion doping step.

The cathode 14 in FIG. 1 has an upper surface 14A and a lower surface 14B. In this embodiment, both the upper surface 14A and the lower surface 14B are non-planar, and the method of forming the non-planar surface is, for example, forming a plurality of grooves on the surface. Please refer to FIG. 2, in which FIG. 2 is a schematic diagram of the three-dimensional structure of the cathode, and the cathode in FIG. 1 is a cross-sectional view along the cross-sectional line A-A′ in FIG. 2. As shown in FIG. 2, in this embodiment, the cathode 14 is a dome-shaped structure, having an upper surface 14A, a lower surface 14B (not shown in FIG. 2, please refer to FIG. 1) and a sidewall 14C. The upper surface 14A and the lower surface 14B of the cathode 14 contain a plurality of grooves 15, wherein the grooves 15 are preferably circular in the top view, and the grooves 15 are arranged in concentric circles with different sizes. The purpose of forming the groove 15 on the surface of the cathode 14 is to increase the surface area of the cathode 14. According to the experimental results of the applicant, when the hot electrons generated by the filament 12 hit the cathode 14, the larger the surface area of the cathode 14 is, the more hot electrons will be generated after being hit by the hot electrons. That is, increasing the surface area of the cathode 14 can improve the generation efficiency of hot electrons, thereby increasing the ion implantation speed of the ion implanter.

In addition, in this embodiment, the groove 15 is designed to be circular (ring shape), and a plurality of grooves 15 are arranged in concentric circles, so that sharp corners can be avoided at the edges of the grooves 15. If the surface of the cathode 14 has some sharp corners, it is easy to generate discharge and affect the manufacturing process. Therefore, in the present invention, the groove 15 on the surface of the cathode 14 is designed to be circular, which can reduce the possibility of discharge of the cathode 14.

In this embodiment, the ratio of the depth of the groove 15 to the total thickness of the cathode 14 (here, the total thickness of the cathode 14 is the distance from the upper surface 14A to the lower surface 14B) can be controlled between 0.1 and 0.2. When the depth of the groove 15 is controlled within this range, the surface areas of the upper surface 14A and the lower surface 14B of the cathode 14 can be effectively increased, but the structural stability of the cathode 14 will not be affected because the groove is too deep. According to the applicant's experiment, compared with the smooth and flat cathode surface, in this embodiment, forming multiple grooves 15 on the upper surface 14A and the lower surface 14B of the cathode 14 can increase the surface area by about 47%. In addition, when the doping source gas with the same concentration is introduced, it is measured that the intensity of the generated ion beam increases by about 10%˜15%, and the productivity of the ion implanter increases by about 5%.

In this embodiment, the upper surface 14A and the lower surface 14B of the cathode 14 are both provided with grooves 15, but in other embodiments of the present invention, grooves may only be formed on one of the upper surface or the lower surface, and such a structure is also within the scope of the present invention.

In addition, in this embodiment, as shown in FIGS. 1 and 2, the cathode 14 is designed as a cylinder, and the arc chamber 10 is also designed as a hollow cylinder. However, the present invention is not limited to the shape of the cathode 14 or the arc chamber 10, and the actual shape can be adjusted according to requirements. If the cathode surface is a non-flat surface, especially the non-flat surface formed by grooves, it should be within the scope of the present invention.

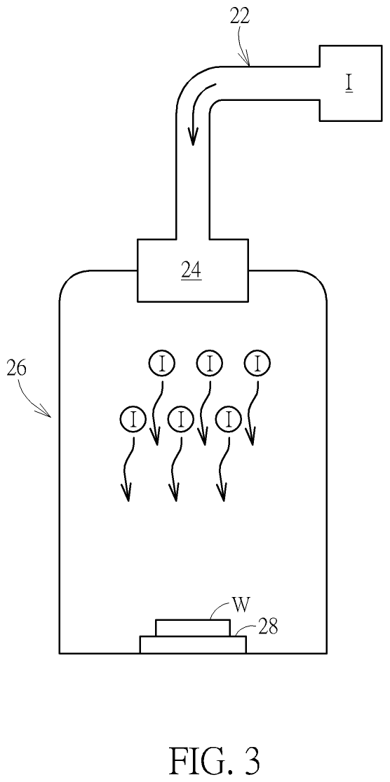

It should be noted that the structure shown in FIG. 1 above belongs to the ion source structure 1 in the ion implanter, that is, it is not the whole structure of the ion implanter. After the ion source structure 1 generates ions, the ions are implanted into the substrate through other devices. For example, ions are guided through a pipeline and an ion accelerator is used to generate an ion beam, and the ion beam is introduced into the chamber where the semiconductor wafer is located, so as to carry out ion implantation of the wafer. More specifically, please refer to FIG. 3, which shows a schematic diagram of the ion implantation step in which ions generated by an ion source structure in an ion implanter are guided into a chamber. As shown in FIG. 3, after the ion source structure 1 (here, the ion source structure 1 is the same as the ion source structure 1 shown in FIG. 1 above) generates ions I, the ions I travel to an ion accelerator 24 through a pipeline 22, and the ions I passing through the ion accelerator 24 are accelerated and emitted into a chamber 26, in which a wafer W is placed in the chamber 26, and some patterns or masks on the wafer W may block the implantation of ions I, while the exposed areas of the remaining wafer W can be used for ion implantation. A negative voltage can be applied to the wafer pedestal 28, so that the ions I can be attracted to advance toward the wafer W, and the ions I after passing through the ion accelerator 24 can be implanted into the desired area on the wafer W.

According to the above description and drawings, the present invention provides an ion source structure of an ion implanter, which comprises an arc chamber 10, a filament 12, and a cathode 14, wherein the cathode 14 has an upper surface 14A and a lower surface 14B, and at least one of the upper surface 14A and the lower surface 14B is non-planar.

In some embodiments of the present invention, at least one of the upper surface 14A or the lower surface 14B contains a plurality of grooves 15.

In some embodiments of the invention, the plurality of grooves 15 are circular grooves.

In some embodiments of the present invention, the circular grooves have different sizes and are arranged in a concentric circle.

In some embodiments of the present invention, the ratio of a depth of the groove 15 to a total thickness of the cathode is 0.1 to 0.2.

In some embodiments of the present invention, the arc chamber 10 is a hollow cylindrical structure, in which the filament 12 and the cathode 14 are both located in the arc chamber, and the filament 12 and the cathode 14 are not in direct contact.

Some embodiments of the present invention further include a first power supply unit 16 electrically connected to both ends of the filament 12.

In some embodiments of the present invention, a second power supply unit 18 is further included, which is electrically connected with one end of the filament 12 and the cathode 14.

In some embodiments of the present invention, the cathode 14 is a cylindrical cover structure with an non-planar top surface structure (i.e., upper surface 14A and lower surface 14B) and a cylindrical side wall 14C.

In addition, the present invention provides an operation method of an ion source of an ion implanter, which includes providing a wafer W with a pattern, providing an ion implanter, wherein an ion source structure 1 in the ion implanter includes an arc chamber 10, a filament 12 is located in the arc chamber 10, and a cathode 14 is located in the arc chamber 10, wherein the cathode 14 has an upper surface 14A and a lower surface 14B, wherein at least one of the upper surface 14A or the lower surface 14B is non-planar, and the ion implanter is used to perform an ion implantation step on the wafer.

The invention is characterized in that the ion source in the ion implanter comprises a cathode with a non-planar surface, and hot electrons are generated after the filament in the arc chamber is heated, and the hot electrons hit the cathode and generate more hot electrons. Because the surface of the cathode is designed as a non-flat surface, its surface area is large, which can improve the generation efficiency of hot electrons, and then improve the generation efficiency of ion beams. The invention can achieve the advantage of improving productivity without increasing the flow rate of doping gas and being compatible with the existing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ion source structure of an ion implanter, comprising:
an arc chamber;
a filament located in the arc chamber; and
a cathode located in the arc chamber, wherein the cathode has an upper surface and a lower surface, and at least one of the upper surface and the lower surface is non-planar.

2. The ion source structure of an ion implanter according to claim 1, wherein at least one of the upper surface or the lower surface contains a plurality of grooves.

3. The ion source structure of an ion implanter according to claim 2, wherein the plurality of grooves are circular grooves.

4. The ion source structure of an ion implanter according to claim 3, wherein the circular grooves have different sizes and are arranged in a concentric circle.

5. The ion source structure of an ion implanter according to claim 2, wherein the ratio of a depth of the groove to a total thickness of the cathode is 0.1 to 0.2.

6. The ion source structure of an ion implanter according to claim 1, wherein the arc chamber is a hollow cylindrical structure, wherein both the filament and the cathode are located in the arc chamber, and the filament is not in direct contact with the cathode.

7. The ion source structure of an ion implanter according to claim 1, further comprising a first power supply unit electrically connected to both ends of the filament.

8. The ion source structure of an ion implanter according to claim 1, further comprising a second power supply unit electrically connected one end of the filament and the cathode.

9. The ion source structure of an ion implanter according to claim 1, wherein the cathode is a cylindrical cover structure with a non-planar top surface structure and a cylindrical side wall.

10. An operation method of an ion source structure of an ion implanter, comprising:
providing a wafer with a pattern;
an ion implanter is provided, wherein an ion source structure in the ion implanter comprises:
an arc chamber;
a filament located in the arc chamber;
a cathode located in the arc chamber, wherein the cathode has an upper surface and a lower surface, and at least one of the upper surface and the lower surface is non-planar; and
using the ion implanter to perform an ion implantation step on the wafer.

11. The operation method of an ion source structure of an ion implanter according to claim 10, wherein at least one of the upper surface or the lower surface contains a plurality of grooves.

12. The operation method of the ion source structure of an ion implanter according to claim 11, wherein the plurality of grooves are circular grooves.

13. The operation method of the ion source structure of an ion implanter according to claim 12, wherein the circular grooves have different sizes and are arranged in a concentric circle.

14. The operation method of the ion source structure of an ion implanter according to claim 11, wherein the ratio of a depth of the groove to a total thickness of the cathode is 0.1 to 0.2.

15. The operation method of the ion source structure of an ion implanter according to claim 10, wherein the arc chamber is a hollow cylindrical structure, wherein both the filament and the cathode are located in the arc chamber, and the filament is not in direct contact with the cathode.

16. The operation method of the ion source structure of an ion implanter according to claim 10, wherein the ion source structure in the ion implanter further comprises a first power supply unit electrically connected to both ends of the filament.

17. The operation method of the ion source structure of an ion implanter as claimed in claim 10, wherein the ion source structure in the ion implanter further comprises a second power supply unit electrically connected with one end of the filament and the cathode.

18. The operation method of the ion source structure of an ion implanter according to claim 10, wherein the cathode is a cylindrical cover structure with a non-planar top surface structure and a cylindrical side wall.
